(19) United States
(12) Patent Application Publication
(10) Pub. No.: US 2024/0347395 A1
(43) Pub. Date: Oct. 17, 2024

(54) OBJECT DIMENSIONING APPARATUS AND RELATED METHODS

(71) Applicant: Quantronix, Inc., Farmington, UT (US)

(72) Inventors: Brandon M. Taylor, Kaysville, UT (US); Heath A. Pritchett, Kaysville, UT (US); Justin G. Norman, West Point, UT (US); Brett C. Behrmann, Farmington, UT (US); Robert L. Kennington, Kaysville, UT (US); Randy B. Nielsen, Kaysville, UT (US); Brandon L. Baker, Farmington, UT (US)

(21) Appl. No.: 18/299,862

(22) Filed: Apr. 13, 2023

(51) Int. Cl. H01L 21/66; B23K 26/03; B23K 26/042; H01L 21/67

(52) U.S. Cl. CPC H01L 22/12; B23K 26/032; B23K 26/042; H01L 21/67259

(57) ABSTRACT

An apparatus for measuring dimensions of an object comprises a horizontal table and two mutually perpendicular walls above the table forming a junction, a first device positioned opposite one wall for emitting a horizontal laser line beam toward and perpendicular to the one wall and movable horizontally along the table parallel to the one wall, a second device positioned above the table for emitting a vertical laser line beam toward and perpendicular to table and movable horizontally parallel to the table and another wall above and across the table, and a third device positioned opposite to the one wall for emitting a horizontal laser line beam toward and perpendicular to the one wall and movable vertically parallel to the other wall. Other apparatus and methods of measuring one or more object dimensions are also disclosed.

### TECHNICAL FIELD

Embodiments of the present disclosure relate generally to methods and apparatus for taking dimensional measurements of objects and, optionally, object weight.

### BACKGROUND

Millions of packages per year are handled and shipped by United Parcel Service, Federal Express, and many other smaller courier and delivery services. These packages originate with federal, state, and local governments as well as private businesses of all sizes. In many instances, the charges by the carriers to their customers are based on the so-called “dim-weight factor” or “dimensional weight factor” (DWF) of the article being shipped, a fictitious dimension based on length (L) times width (W) times height (H) in inches divided by a standard agency or association-recognized divisor or conversion factor, commonly 139 ((L×W×H)/139) for international shipments and 166 ((L×W×H)/166) for domestic U.S. shipments. The “139” and “166” divisors or conversion factors have been recognized and adopted by the International Air Transport Association (I.A.T.A.). Even if an object or package is of irregular configuration, the “dim weight,” using the longest measurement each of length, width, and height of the object, is still utilized for billing purposes. The volume computed by multiplication of object length, times width, times height may hereinafter be termed the “cubic volume,” “spatial volume,” or simply the “cube” of the object.

The measurements of the articles shipped are also critical so that the carrier can compute volume-based shipping charges; accurately determine the number of containers, trucks, trailers, or other vehicles required to transport goods to their destinations; and handlers of goods can optimize the use of space in retail as well as warehouse/distribution-center facilities. In addition, article weight and measurement s may also be used to determine and predict weight and balance for transport vehicles and aircraft and to dictate the loading sequence for objects by weight and dimensions for maximum safety and efficiency. If orders of any items are to be packed into boxes, knowledge of object weight and dimensions is useful for determining box size, durability, packing sequence and product orientation.

A quick, accurate means and method for determining the dimensions and the cubic volume or spatial volume of a variety of sizes of packages and other objects in a commercial or industrial setting has been lacking for some situations. There is a particular need to be able to accurately measure and weigh packages and other objects of varying dimensions and sizes, including both small and large packages, as well as irregularly shaped packages and objects in certain low volume situations which may not warrant the use of commercially available apparatus, or for which situations commercially available apparatus are unduly expensive. In addition, in situations where an object, particularly a non-cuboidal or irregularly shaped object, requires packaging (e.g., fabrication of a box to contain the object), it would be desirable to have an apparatus and method to accurately measure maximum length, width and height of such an object in a relatively quick and inexpensive manner to provide the measured dimensions for fabricating a suitable box of adequate yet minimum dimensions.

The inventors herein have developed an apparatus fabricated with high quality, low-cost components that may be operated to provide a cost-effective solution for end customers.

### BRIEF SUMMARY

Embodiments of the present disclosure comprise an apparatus and method for determining the dimensions and, optionally, spatial volume and weight of an object.

In one embodiment, an apparatus for measuring dimensions of an object comprises a horizontal table, a vertical wall extending longitudinally and upwardly from the horizontal table, and another vertical wall extending laterally and upwardly from the table perpendicular to the vertical wall, the table and the vertical walls meeting at a junction for placement of an object to be measured in contact with a surface of the table and each vertical wall. The apparatus also comprises a first device positioned opposite the vertical wall and movable horizontally along the table parallel to the vertical wall, the first device configured to emit a horizontal laser line beam toward and perpendicular to the vertical wall, a second device positioned above the table and movable parallel to the table and perpendicular to the vertical wall above and across the table, the second device configured to emit a vertical laser line beam toward and perpendicular to the table, and a third device positioned opposite to the vertical wall and movable parallel to the other vertical wall and vertically above the table, the third device configured to emit a horizontal laser line beam toward and perpendicular to the vertical wall.

In another embodiment, an apparatus for measuring dimensions of an object comprises a horizontal table, a vertical wall extending longitudinally and upwardly from the horizontal table, and another vertical wall extending laterally and upwardly from the table perpendicular to the vertical wall, the table and the vertical walls meeting at a junction for placement of an object to be measured in contact with a surface of the table and each vertical wall. The apparatus also comprises at least one first set of one or more printed circuit boards (PCBs) positioned over the table extending from proximate the other vertical wall along the table parallel to the vertical wall, at least one second set of one or more PCBs positioned over the table and extending from proximate the vertical wall along the table perpendicular to the vertical wall, and at least one third set of one or more PCBs positioned over and along the vertical wall or the other vertical wall and extending vertically from proximate the table, each of the PCBs configured with longitudinally adjacent touch-sensitive segments and configured to transmit a signal corresponding to a location of a touch-sensitive segment responsive to placement of an operator digit over or in contact with that respective segment.

In a further embodiment, a method of measuring dimensions of an object comprises placing an object to be measured at a junction of a table surface and surfaces of two mutually perpendicular vertical walls, emitting a first laser beam horizontally over the table surface toward the object and perpendicular to one of the vertical walls, moving the first laser beam horizontally from a position where the object interferes with the laser beam until the object no longer interferes with the laser beam, and determining a horizontal distance of the first laser beam from the junction, emitting a second laser beam vertically over the table surface toward the object and perpendicular to the table surface, moving the second laser beam horizontally from a position where the object interferes with the second laser beam until the object no longer interferes with the second laser beam, and determining a horizontal distance of the second laser beam from the junction, and emitting a third laser beam horizontally over the table surface toward the object and perpendicular to the surface of the one of the vertical walls, moving the third laser beam vertically from a position where the object interferes with the third laser beam until the object no longer interferes with the third laser beam, and determining a vertical distance of the third laser beam from the junction.

### BRIEF DESCRIPTION OF THE DRAWINGS

FIG. 1 is a perspective view of an embodiment of an apparatus of the disclosure;

FIG. 2 is a frontal elevation of the apparatus embodiment of FIG. 1;

FIG. 3 is an end elevation of the apparatus embodiment of FIG. 1;

FIG. 4 is a top elevation of the apparatus embodiment of FIG. 1;

FIG. 5 is a schematic diagram of components and functions of an embodiment of a smart handle of the disclosure;

FIG. 6 is a schematic diagram of a main controller and display in combination with internal apparatus interfaces with smart handles and an external interface;

FIG. 7 is a top elevation of a printed circuit board configured for use in another embodiment of the disclosure employing capacitive touch technology;

FIG. 8 is a perspective view of another embodiment of an apparatus of the disclosure employing capacitive touch technology;

FIG. 9 is a perspective view of a variant of the embodiment of FIG. 8 employing capacitive touch technology;

FIG. 10 is a rendering of an embodiment of an apparatus of the disclosure incorporated into a larger system;

FIG. 11A is a perspective view of a portion of a variation of the embodiment of FIGS. 1 through 4; and

FIG. 11B is a rear elevation of the variation of FIG. 11A.

### DETAILED DESCRIPTION

Disclosed embodiments of apparatus may be characterized for the sake of convenience as “dimensioning tables” comprising a horizontal table and two vertically extending walls, one wall lengthwise over the table opposite an operator location side and another wall at a right angle (i.e., 90°) to the one wall and extending toward the operator location side. The other wall may be at the left-hand side or right-hand side of the operator location. Surfaces of the vertical walls and horizontal table are used to provide a zero point for justification of the object being measured. In some embodiments, measurements of length, width and height of the object may be effected by three “smart handles” each linearly movable on a slide track in conjunction with a linear encoder associated with the respective slide track in a direction mutually perpendicular to a direction of movement of the other two smart handles. When initiated by an operator, each smart handle emits a laser line aimed at and perpendicular to a surface (i.e., horizontal table surface, vertical wall surface) opposite and parallel to its respective slide track. An operator may move each smart handle along its slide track until its laser line is no longer broken by interference of the object and may be visually observed by the operator, at which point the operator may initiate a capture command (e.g., press a capture button) on the smart handle to indicate, via the associated linear encoder, the smart handle position and dimension of the object. Optionally, the smart handles may each be equipped with a camera to automatically detect the absence of a laser line break. In other embodiments, capacitive touch technology using printed circuit boards with segmented circuit traces indicating distances from a reference point may be employed.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles between surfaces that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale.

In the description and for the sake of convenience, the same or similar reference numerals may be used to identify features and elements common between various drawing figures.

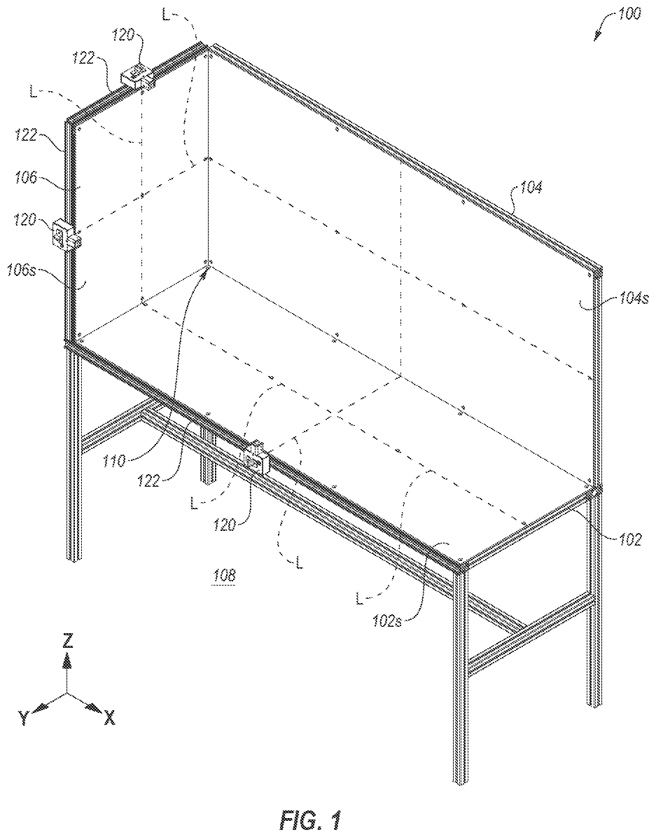

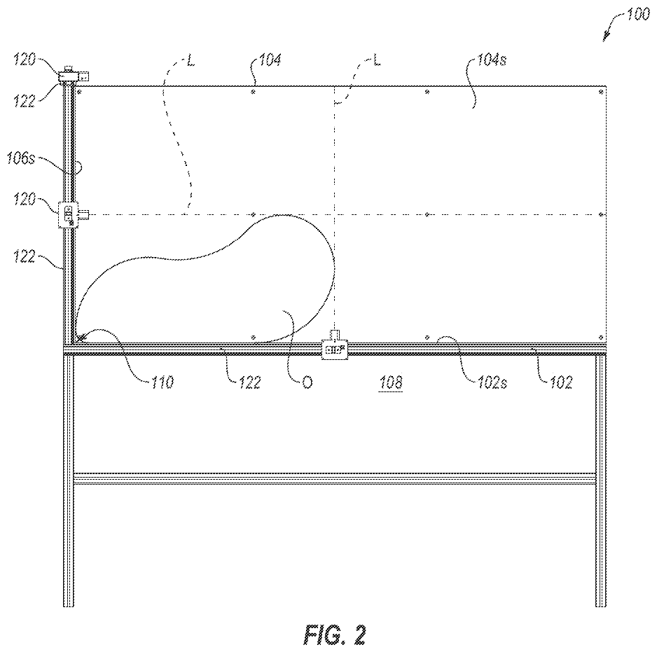

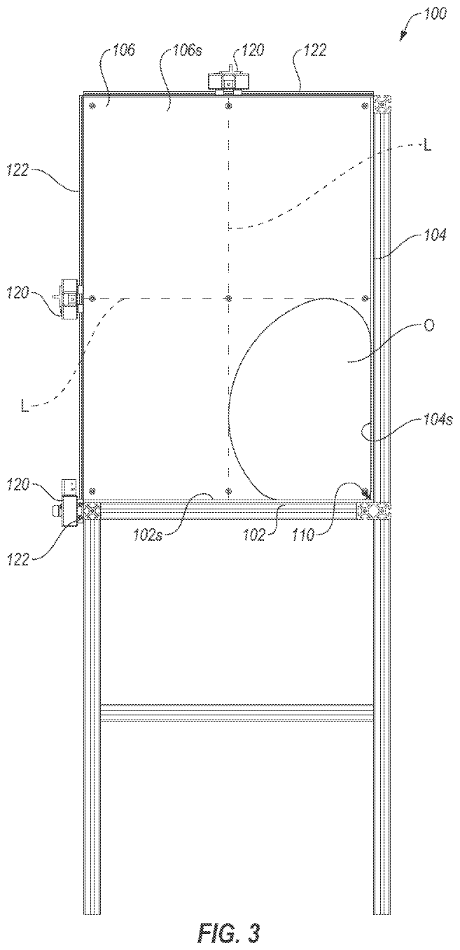

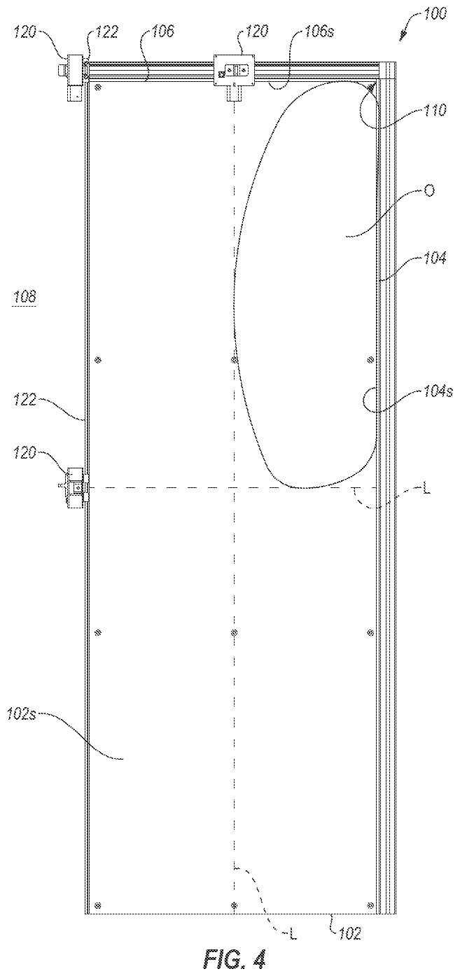

Referring now to FIGS. 1 through 4, dimensioning table 100 supported by a leg assembly or other support structure (e.g., cabinet on rollers) comprises a rigid horizontal table 102 having a surface 102s for supporting an object to be measured, a vertical wall 104 having a surface 104s and running longitudinally along a side of table 102 and another vertical wall 106 having a surface 106s and oriented at a right angle (i.e., 90°) to vertical wall 104, vertical wall 106 extending toward an operator location 108 proximate to a side of table 102 opposite vertical wall 104. A junction 110 of table surface 102s and vertical wall surfaces 104s and 106s provides a location for placing an object to be measured in contact with surfaces 102s, 104s and 106s.

Three movable devices in the form of “smart” handles 120 used to perform the respective length, width and height measuring functions are deployed on dimensioning table 100, each handle 120 being attached to a slide track 122 to be movable linearly along one of three mutually perpendicular (i.e., X, Y and Z) axes (see FIG. 1). As illustrated and by way of non-limiting example, one smart handle 120 may be carried on a slide track 122 running longitudinally along an edge of table 102 adjacent to the operator location 108, a second smart handle 120 may be carried by a slide track 122 running along an edge of vertical wall 106 adjacent to the operator location 108, and a third smart handle 120 may be carried by a slide track 122 running along a top edge of vertical wall 104.

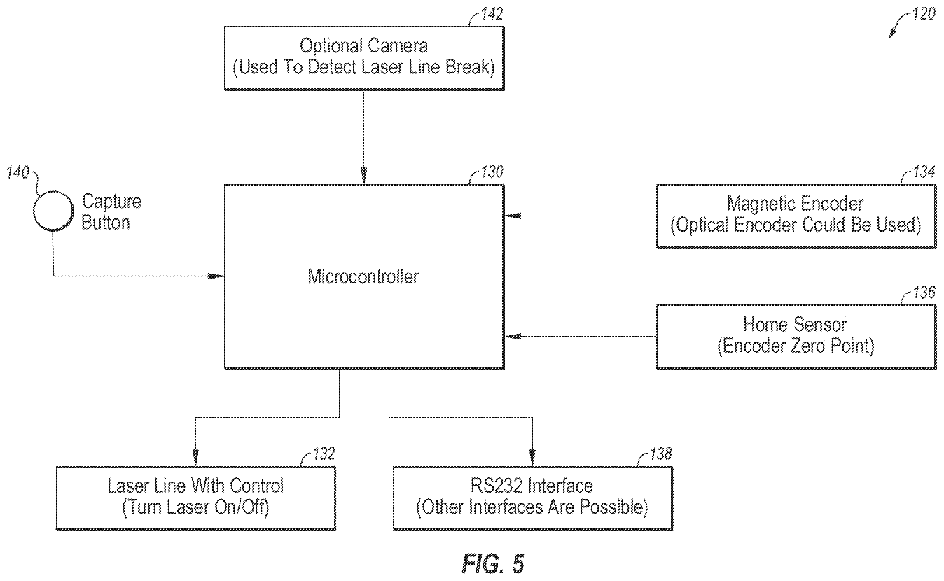

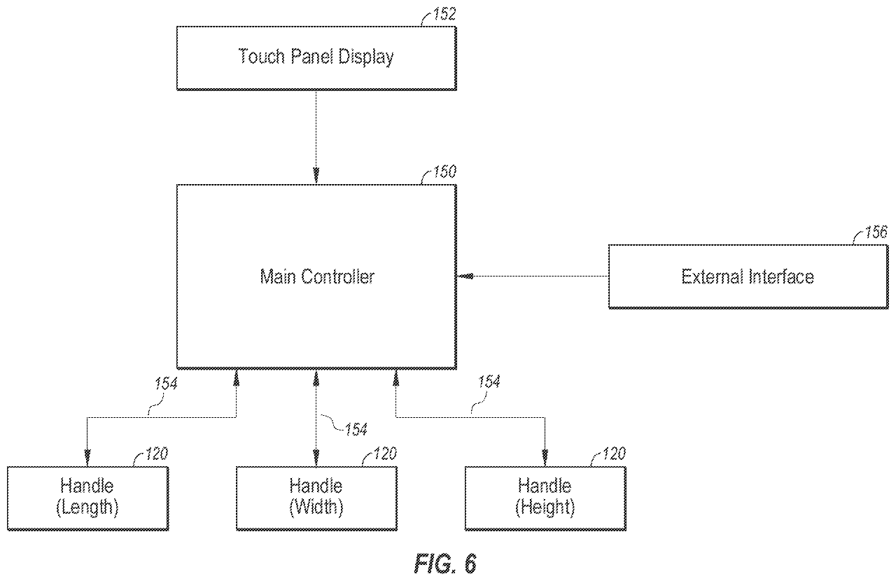

As depicted in FIG. 5 indicating the elements and functions of smart handles 120 completed by firmware, each smart handle 120 comprises a microcontroller 130 operably coupled to a laser line generator (to be referred to herein for convenience as a “laser line”) 132 with on/off control, a magnetic or optical encoder 134 carried by the smart handle 120 for outputting a location of smart handle 120 along its respective slide track 122, a home sensor 136 for detecting a reference (starting) point for the smart handle 120 and an RS 232 or other suitable interface 138 for communicating with a main controller 150 (FIG. 6) for dimensioning table 100. A capture element (e.g., button) 140 may be employed to initiate a signal from an encoder 134 indicating the location of a smart handle 120 at a laser line break corresponding to a length, width or height of an object being measured. As another approach, a single capture button 140 may initial length, width and height signals after all smart handles 120 are in a measurement position. Optionally, a camera 142 may be incorporated into each smart handle 120 to detect and signal a laser line break associated with that particular smart handle 120 so that movement of that respective smart handle 120 can be stopped by the operator. Suitable cameras are commercially available. In a further modification of the smart handles 120, a drive motor may be incorporated in each smart handle 120 to move the respective smart handles 120 along their associated slides 122 responsive to an initiation command from main controller 150 triggered by the operator, such movement to be stopped responsive to a signal from the associated camera 142 upon detection of a laser line break and a signal indicative of the respective dimension measured by the smart handle 120 sent by microcontroller 130 to main controller 150.

Depending on the option of adding a camera 142, two possible microcontroller options may be employed. If using a camera, a more expensive and more capable commercially available microcontroller 130 is desirable. Without the camera, and for a lower cost solution, a microcontroller 130 from Atmel/Microchip may be employed, for example, Part Number ATSAMS70J21A-AN.

The linear magnetic or optical encoder 134 may be used to perform the measurement of an object dimension by each smart handle 120. The encoder 134, as part of the smart handle 120, monitors the motion of the smart handle 120 as it is moved along the axis of movement for a particular dimension. The encoder includes quadrature features so that direction of the handle 120 can be determined, as necessary, for accurate measurements. One suitable encoder is a magnetic encoder from Renishaw, Part Number RLC2ICA03BB12B00. This encoder operates by using an incremental magnetic scale attached along the axis. An incremental magnetic encoder module scans along the magnetic scale to determine position of the smart handle from the zero or other reference point, and thus the associated dimension of the object. An optical encoder may also be used. Such encoders work by using a wheel attached to the encoder that spins against the underlying structure surface, determining the dimension.

The home sensor 136 may be used as a reference point for a starting position for the smart handle 120 from which measurements are taken. The home sensor 136 may be a Hall effect type sensor carried by each smart handle 120 that is triggered by a stationary magnet at the home position when the smart handle is in proximity to (e.g., over) the magnet. Another home sensor option with a magnetic encoder would be to embed a fiducial into the magnetic scale to represent the home position. Other options for a home sensor may be used. Note the home position may not be a zero point for a particular dimension, but may be offset from zero in the direction of intended movement of the smart handle for object measurement to allow for clearance of the smart handle from a wall or table surface. Accordingly, the offset is added to the measured distance by the microcontroller associated with the respective smart handle, or the main controller, to arrive at an object dimension.

The capture button 140 may be used to capture the object dimension measurement from the current position of the smart handle 120. The capture button 140 may also be used to tell the microcontroller 130 to request the measurement from all the smart handles 120 after the last smart handle 120 is positioned. The capture button 140 may be a mechanical switch, a capacitive touch switch, or other suitable commercially available switch.

An eye-safe laser line 132 may be used to emit a laser line beam L onto a perpendicular opposing surface of dimensioning table (i.e., wall surface, table surface) to find the outer edge (from the zero point) of the object being measured in a given direction. Finding the edge of the object is done by moving the smart handle 120 away from the junction 110 just past the object until the laser line beam L is no longer broken by that object. This approach gives a good visual indicator for the operator, not dependent on specific operator position, that a proper measurement will be taken. As one option, by way of non-limiting example, the laser line 132 may be initiated to generate a laser line beam L by detection of movement of the smart handle 120. Suitable laser lines include Quarton VLM-635 and VLM-650 lasers.

An RS232 communication interface 138 may be used to communicate dimension information from the microcontroller 130 of each smart handle 120 to the main controller 150 (FIG. 6). Other information, such as calibration commands, laser control commands, etc., may also use this interface. However, RS232 communication is not the only type that may be used as USB, ethernet, and other communication interface protocols are options.

The main controller 150 interfaces with all the smart handle microcontrollers 130 and performs communication tasks to outside devices or networks as described further below. The main controller 150 is also designed to be the interface for the operator, including displaying the measurement results on an LCD or other display 152. Interfaces 154 of main controller 150 with other active components (i.e., smart handles 120) of dimensioning table 100 as well an external interface 156 are shown in FIG. 6.

The touch panel display 152 may be a 4-wire resistive touch over a 4.3 inch LCD display. However, other commercially available display technologies are suitable.

The main controller 150 may be based on the NXP LPC4357 microcontroller. However, other commercially available suitable microcontroller exist.

The length, width, and height smart handles 120 may each communicate with the main controller 150 using RS232 communication protocol for interface 154. The connection may be a 4-wire connection transferring power (e.g., 12 VDC) to each smart handle 120 as well as the RS232 communications. Other means of communication protocols such as RS422, RS485, USB, Ethernet, etc., may also be employed.

The external interface 156 to the outside world from main controller 150 may, depending on the application, be one of a number of options available with the NXP LPC4357 microcontroller, which offers multiple interfaces including USB, RS232, and Ethernet.

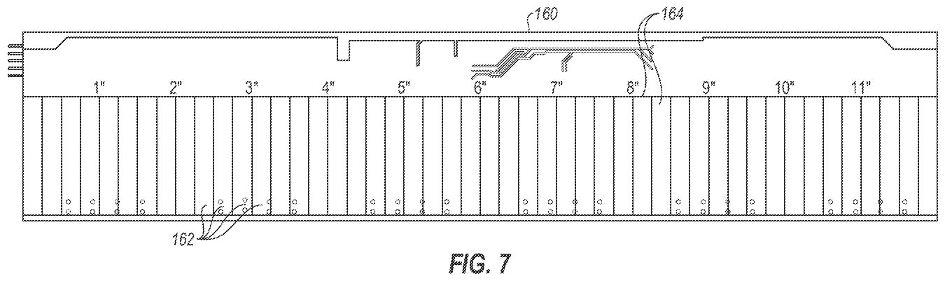

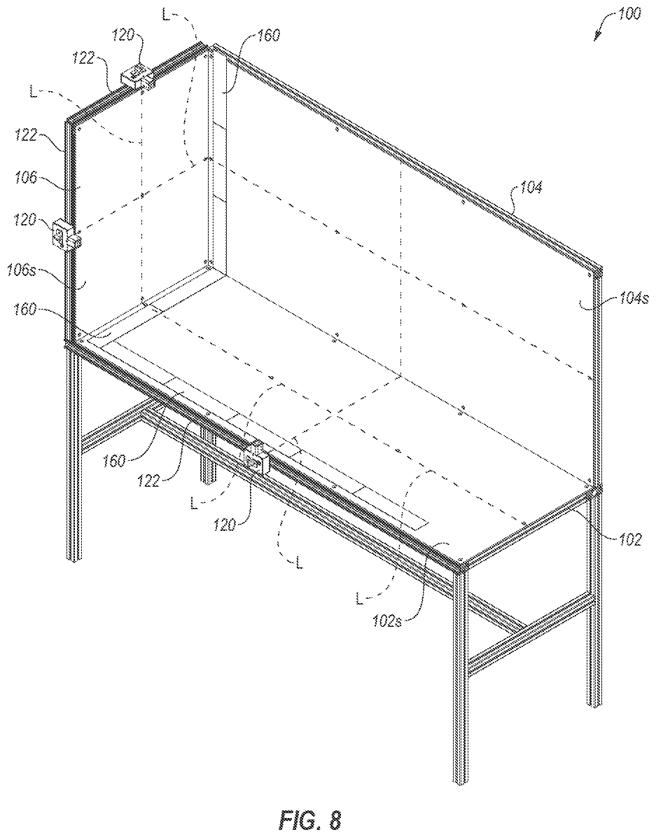

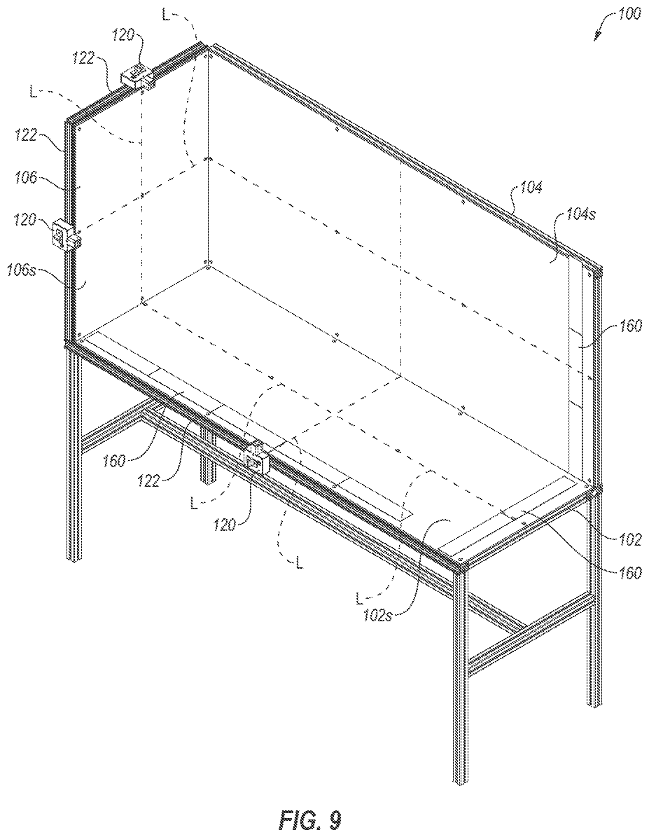

Instead of linear encoders, capacitive touch technology may be used for The dimension measurement process. A custom circuit board (PCB) with an embedded circuit pattern may be used to detect finger presses. See FIG. 7, showing an elongated PCB 160 segmented into 0.25″ rectangles 162, each used to detect a finger press by an operator. Each rectangle 162 includes a circuit trace pattern 164 to detect a finger when the finger enters the proximity of the rectangle 162. Software is then used to determine the location and dimension of the finger press. One design uses a PCB 160 twelve inches in length segmented into forty-eight rectangles 162. Sets of multiple PCBs 160 may be stacked serially end to end to create a larger (i.e., longer) linear assembly providing an extended measurement area for each length, width and height dimension as depicted in FIGS. 8 and 9. As with the linear encoder approach, laser line beams L from laser lines 132 may be used to aid the operator as to which rectangle 162 to press. The operator may adjust the three laser lines 132 so that the unbroken laser line L is established just beyond the object being measured. The operator would then press the rectangle 162 on the PCB that has the laser line L spanning over it to capture the respective measurement. The operator then continues the same process with all axes.

If lasers are not used, additional PCBs 160 may be placed strategically on the dimensioning table 100, as depicted in FIGS. 8 and 9, to make it easier to measure a variety of objects. For certain applications, if the PCBs 160 are placed on the edge of the table, as depicted in FIGS. 8 and 9, smaller objects may be difficult to measure accurately. With the object placed in the corner, it makes it difficult to determine which rectangle to press. Adding additional PCBs 160 sets of mutually parallel, laterally spaced PCBs over the table 102 and, optionally, vertical walls 104, 106 may make it easier to determine the correct segment 162 to press for variously sized objects. A PCB pattern as described would be placed on all axes for length, width and height measurement. Another approach may be to mount each PCB 160 to a slide track 122 secured to the table or to a vertical wall surface and oriented parallel to the respective PCB 160 to allow movement of each respective PCB 160 a more favorable position with respect to an object to measure a given dimension, a position of a PCB on its respective slide track 122 being measured by a linear magnetic or optical encoder 134, the distance from a reference point measured by the linear magnetic or optical encoder 134 responsive to the position of the PCB 160 when a measurement is taken then being used to augment the measurement taken on the PCB 160 and provide a correct magnitude of a given object dimension from the reference point. The capacitive touch design may communicate using an RS232 interface on each PCB 160. With this approach, a suitable microcontroller 130 operably coupled to the PCB or serially placed PCBs 160 for each dimension may be a Microchip/Atmel ATSAMD21E18A-AF microcontroller. Further, an RS422 or RS485 are also suitable options for communication with the main controller 150. The microcontroller 130 associated with PCBs 160 for each dimension communicates to the same main controller 150 described above.

Another option for determining the correct rectangle 162 to press may employ a printed grid of circuit traces on the dimensioning table surfaces themselves including the table surface and the two vertical walls. An operator may then follow the grid traces on each table or wall surface to just past the object to the proper rectangle to be pressed for measuring a particular dimension.

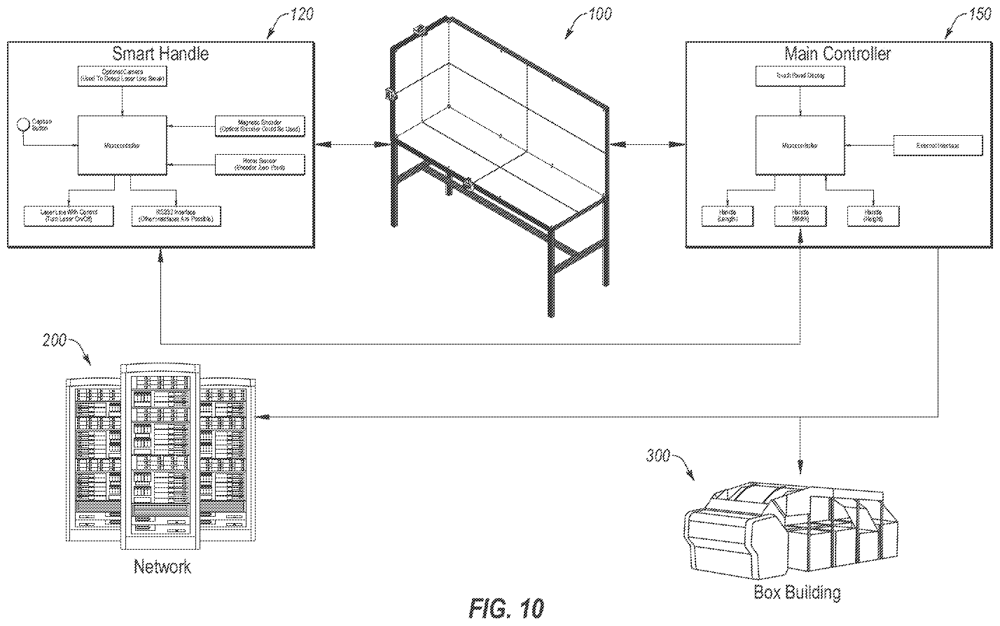

The design of dimensioning table 100 offers a low-cost dimensioner that has the ability to measure irregular shaped objects as well as cuboidal shaped objects. The process for measurement uses a minimum number of acts to acquire accurate dimensions of the object. Further, as shown in FIG. 10, the cooperating components (i.e., smart handles 120 and main controller 150) of dimensioning table 100 may easily interface with an external network 200 of, for example, a warehouse or shipping facility, as well as with a conventional box building machine 300 to automatically fabricate a box for each measured object.

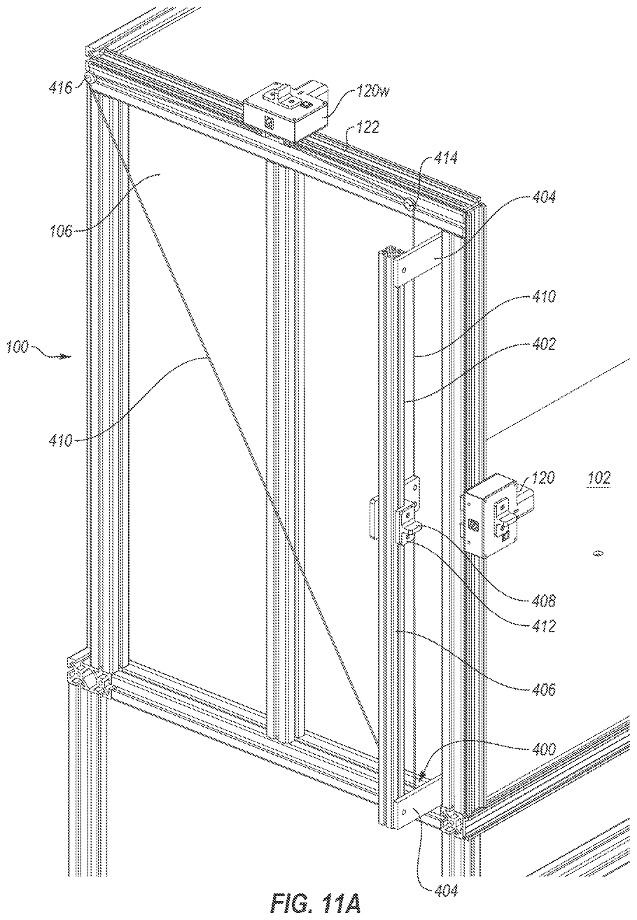

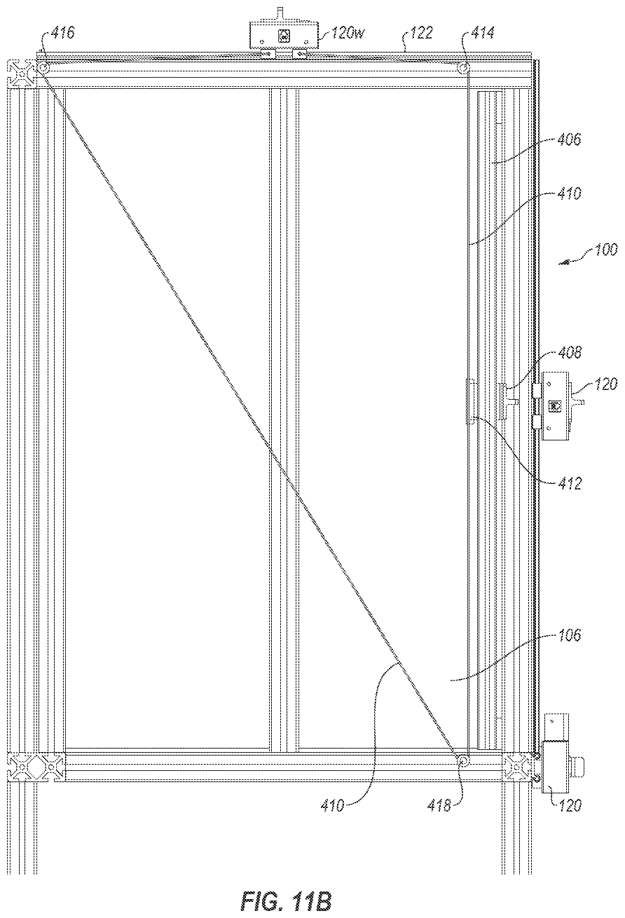

A variation of the embodiment of FIGS. 1 through 4 is depicted in FIGS. 11A and 11B. I has been recognized by the inventor herein that effecting a width measurement of an object by moving the respective smart handle 120w along the top of vertical wall 106 may be difficult for some (e.g., short) individual operators. As depicted in these drawing figures, dimensioning table 100 is substantially the same in structure as depicted in FIGS. 1 through 4, including the location of a smart handle 120w on a slide track 122 extending along an upper edge of vertical wall 106. However, as shown in FIGS. 11A and 11B, an additional position control assembly 400 is added. Specifically, U-shaped bracket 402 includes two legs 404 extending perpendicular to the rear of vertical wall 106 and supporting slide track 406 parallel to vertical wall 106. Position control handle 408 is slidably mounted to slide track 406 and an elongated member in the form of cable 410 is secured to position control handle 408 at location 412. It should be noted that the terms “elongated member” and “cable” as used herein are non-limiting and encompass wire, rope, line and other suitable structures. Cable 410 extends upwardly to a first pulley 414 to the rear of, oriented parallel to, and proximate (e.g., slightly below) the upper edge of vertical wall 106 and rotatable about a horizontal axis extending perpendicular to vertical wall 106 proximate the operator side of dimensioning table 100. Cable 410 extends over first pulley 414 to smart handle 120w on slide track 122 along the upper edge of vertical wall 106, to which smart handle 120w cable 410 is secured. From smart handle 120w cable 410 extends parallel to vertical wall 106 to another, second pulley 416 to the rear of, oriented parallel to, and proximate the upper edge of vertical wall 106 and rotatable about a horizontal axis extending perpendicular to vertical wall 106 opposite the operator side of dimensioning table 100 proximate vertical wall 104. Cable 410 extends horizontally between pulleys 414 and 416 parallel to vertical wall 106 and under smart handle 120w. Cable 410 then extends over second pulley 416 and diagonally downward to yet a third pulley 418 to the rear of and oriented parallel to vertical wall 106 and rotatable about a horizontal axis extending perpendicular to vertical wall 106 proximate the operator side of dimensioning table 100. Third pulley 418 is mounted to dimensioning table 100 at substantially the same elevation as horizontal table 102 and directly below first pulley 414. Cable 410 extends around third pulley 418 and vertically upward past control handle 408 to first pulley 414. With such an arrangement, vertical movement of position control handle 408 by an operator initiates and controls horizontal movement of smart handle 120w along slide track 122 without reaching of the operator to and along the upper edge of vertical wall 106 to grasp smart handle 120w.

In use and operation of the dimensioning table 100 depicted in FIGS. 1 through 4, in an acquisition act, the dimensioning table 100 is powered on, all smart handles 120 are moved into their “home” positions for zeroing the encoders 134 and to have a place of reference from which to start measuring. As shown in FIGS. 1 through 4, the home position for the length measuring handle 120 would be justified to the left most position of the length slide track 122. The home position for the width measuring handle 120 would be justified along its slide track 122 furthest away from the operator and close to the back vertical wall 104. The home position for the height measuring handle 120 would be toward the bottom of its slide track 122 close to the table surface 102s. This calibration only needs to be done once on power up of the apparatus, unless, for some reason an encoder 134 has lost track of its position. The operator of the apparatus justifies the object being measured on the table surface 102s against the wall surface 106s to the left and pushed up against the wall surface 104s opposite of the operator (i.e., the object is pushed into the corner of the two walls 104, 106 abutting junction 110). The operator may identify the object by scanning a barcode attached to the object. Barcode information may be sent to the main controller 150 via USB or serial interface.

The operator will move the “length” smart handle 120 along the slide track 122 lengthwise until the beam from laser line 132 has moved off the object being measured and establishes an unbroken laser line beam L on the back wall surface 104s and the table surface 102s. As the length smart handle 120 is moving, an encoder 134 built into the smart handle 120 is monitoring the movement and keeping track of the distance away from the home position. The operator will move the “width” smart handle 120, pulling it along the slide track widthwise (or toward the operator, away from the back wall) until the beam from laser line 132 has moved off the object being measured and establishes an unbroken laser line beam L on the left side wall surface 106s and the table top surface. 102s. As the width smart handle 120 is moving along its slide track 122, an encoder 134 built into the smart handle 120 is monitoring the movement and keeping track of the distance away from the home position. The operator will move the “height” smart handle 120, pulling it up along the slide track 122 height-wise (or toward the ceiling or away from the table top surface) until the laser line beam from laser line 132 has moved off the object being measured and establishes an unbroken laser beam line L on the left side wall surface 106s and the back wall surface 104s. As the height smart handle 120 is moving, an encoder 134 built into the smart handle 120 is monitoring the movement and keeping track of the distance away from the home position. After all the unbroken laser line beams L are positioned, the capture button 140 on the height measuring smart handle 120 may be pressed, telling the main controller 150 that all the smart handles 120 are in measuring position. The main controller 150 may then request the current measurement from each of the smart handles 120. The data collected from all the smart handles 120 may then be passed onto other devices, networks, box building machine, etc.

It should be noted that the above acts may be done in a different sequence. For example, while the acts above dictate moving the length smart handle first, then the width, then the height and pressing the height button. The measuring sequence may be done in any order, and capture button on any smart handle may be pressed to signal the controller to request the measurement.

Embodiments of the disclosure described and illustrated are by way of example only, and numerous modifications and enhancements to such embodiments are contemplated as falling within the scope of the disclosed technology. Such enhancements may include, without limitation, the incorporation of a scale into table 102 to weigh an object being measured concurrently with measurement. Further, ball or cylindrical rollers may be incorporated in table 102 to facilitate object movement toward and placement at junction 110. The table 102 may be conveyorized with, for example, a motorized belt conveyor to move an object toward and in contact with a “home” side wall 106, stopping upon contact with the wall or under control of a foot pedal or wireless or table-top controller. Wireless communication may be used to send data from dimensioning table 100 to an application for a smartphone, tablet or other wireless device. Instead of manual movement of smart handles 120 with laser lines 132 on slide tracks 122, such movement may be motorized, and initiated using a wireless or tabletop controller, smart handle movement being stopped when an unbroken beam line L from a laser line 132 is recognized by a camera 142 carried by the same smart handle 120.

As used herein, the terms “comprising,” “including,” “containing,” “characterized by” and grammatical equivalents thereof are inclusive or open-ended terms that do not exclude additional, unrecited elements or method acts, but also include the more restrictive terms “consisting of” and “consisting essentially of” and grammatical equivalents thereof.

As used herein, the term “may” with respect to a material, structure, feature or method act indicates that such is contemplated for use in implementation of an embodiment of the disclosure and such term is used in preference to the more restrictive term “is” so as to avoid any implication that other compatible materials, structures, features and methods usable in combination therewith should, or must be, excluded.

As used herein, the terms “longitudinal.” “vertical,” “lateral,” and “horizontal” are in reference to a major plane of a substrate (e.g., base material, base structure, base construction, etc.) in or on which one or more structures and/or features are formed and are not necessarily defined by earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate.

As used herein, spatially relative terms, such as “beneath,” “below.” “lower,” “bottom,” “above,” “over,” “upper.” “top,” “front.” “rear.” “left.” “right.” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “over” or “above” or “on” or “on top of” other elements or features would then be oriented “below” or “beneath” or “under” or “on bottom of” the other elements or features. Thus, the term “over” can encompass both an orientation of above and below, depending on the context in which the term is used, which will be evident to one of ordinary skill in the art. The materials may be otherwise oriented (e.g., rotated 90 degrees, inverted, flipped), and the spatially relative descriptors used herein interpreted accordingly.

As used herein, the singular forms “a,” “an,” and “the” are intended to include the plural forms as well unless the context clearly indicates otherwise.

As used herein, the terms “configured” and “configuration” refer to a size, shape, material composition, orientation, and arrangement of one or more of at least one structure and at least one apparatus facilitating operation of one or more of the structure and the apparatus in a predetermined way.

As used herein, the term “substantially” in reference to a given parameter, property or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Any reference to an element herein using a designation such as “first,” “second,” and so forth does not limit the quantity or order of those elements unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. Apparatus for measuring dimensions of an object, comprising:
a horizontal table;
a vertical wall extending longitudinally and upwardly from the horizontal table;
another vertical wall extending laterally and upwardly from the table perpendicular to the vertical wall;
the table and the vertical walls meeting at a junction for placement of an object to be measured in contact with a surface of the table and each vertical wall;
a first device positioned opposite the vertical wall and movable horizontally along the table parallel to the vertical wall, the first device configured to emit a horizontal laser line beam toward and perpendicular to the vertical wall;
a second device positioned above the table, movable parallel to the table and perpendicular to the vertical wall above and across the table, the second device configured to emit a vertical laser line beam toward and perpendicular to the table; and
a third device positioned opposite to the vertical wall and movable parallel to the other vertical wall and vertically above the table, the third device configured to emit a horizontal laser line beam toward and perpendicular to the vertical wall.

2. The apparatus of claim 1, wherein each of the first, second and third devices are mounted to a slide track and include a linear encoder configured to measure a distance of movement of the respective device along an associated slide track from a reference point and output a signal corresponding to the measured distance of movement.

3. The apparatus of claim 2, wherein the linear encoders comprise magnetic or optical encoders.

4. The apparatus of claim 2, wherein each of the first, second and third devices includes a microcontroller configured to receive a measured distance signal from an associated linear encoder in response to an initiation signal.

5. The apparatus of claim 2, further including a home sensor associated with each of the first, second and third devices for detecting a reference point from which distance of movement by the linear encoder may be measured.

6. The apparatus of claim 2, further including a capture element associated with one or more of the first, second and third devices for initiating a signal from the linear encoder indicating a distance of an associated smart handle from the reference point.

7. The apparatus of claim 4, wherein each of the first, second and third devices includes a camera aimed parallel to a laser line beam emitted by its respective device and configured to recognize a difference between an unbroken laser line beam and a laser line beam having a break, and each microcontroller is configured, responsive to a recognition signal from the camera, to request a signal from its associated linear encoder indicating a measured distance of the respective smart handle from the reference point.

8. The apparatus of claim 4, wherein each microcontroller is configured to communicate dimension information to a main controller of the apparatus, the main controller having an associated display, the main controller configured to provide an external communication interface for the apparatus.

9. The apparatus of claim 1, further including an elongated printed circuit board configured with serial capacitive touch-sensitive segments parallel to and substantially coextensive with a direction and distance of movement of each of the first, second and third devices, wherein each of the first, second and third devices is configured to emit a respective laser line beam across and parallel to capacitive touch-sensitive segments of an associated printed circuit board.

10. The apparatus of claim 9, further including a microcontroller operably coupled to each elongated printed circuit board and configured to receive a signal responsive to an operator digit being placed over an individual capacitive touch-sensitive segment, to convert the received signal to a distance measured from a reference point and transmit a signal corresponding to the measured distance to a main controller.

11. The apparatus of claim 1, further including a scale for measuring object weight under the table surface.

12. The apparatus of claim 1, wherein a horizontal surface of the table comprises ball or cylindrical rollers.

13. The apparatus of claim 1, wherein a horizontal surface of the table includes a motorized conveyor belt.

14. The apparatus of claim 7, wherein each of the first, second and third devices includes a motor for moving such respective device along its associated slide track, and the microcontroller for such device is configured to stop movement of such respective device responsive to a signal from the camera of such respective device recognizing a laser line beam from such device having a break.

15. The apparatus of claim 1, further including a position control assembly, comprising:
a first pulley rotatable about a horizontal axis and oriented parallel to and to a rear of, the other vertical wall proximate an upper edge thereof;
a second pulley rotatable about the horizontal axis and oriented parallel to and to the rear of, the other vertical wall proximate an upper edge thereof;
a third pulley rotatable about the horizontal axis and oriented parallel to and to the rear of, the other vertical wall proximate an elevation of the horizontal table;
the first and third pulleys being located proximate an operator side of the apparatus and the second pulley being located proximate the vertical wall;
an elongated member extending over the pulleys, vertically between the first and third pulleys, horizontally between the first and second pulleys, and diagonally between the second and third pulleys; and
the second device secured to the elongated member between the first and second pulleys.

16. The apparatus of claim 15, further including a control handle secured to the elongated member between the first and third pulleys.

17. The apparatus of claim 16, wherein the control handle is slidably mounted to a vertical slide track to the rear of the other vertical wall, the vertical slide track mounted at opposing ends to legs secured to and extending perpendicularly to the rear of the other vertical wall.

18. Apparatus for measuring dimensions of an object, comprising:
a horizontal table;
a vertical wall extending longitudinally and upwardly from the horizontal table;
another vertical wall extending laterally and upwardly from the table perpendicular to the vertical wall;
the table and the vertical walls meeting at a junction for placement of an object to be measured in contact with a surface of the table and each vertical wall;
at least one first set of one or more printed circuit boards (PCBs) positioned over the horizontal table extending from proximate the other vertical wall along the table parallel to the vertical wall;
at least one second set of one or more PCBs positioned over the table and extending from proximate the vertical wall along the table perpendicular to the vertical wall; and
at least one third set of one or more PCBs positioned over and along the vertical wall or the other vertical wall and extending vertically from proximate the table; and
each of the PCBs configured with longitudinally adjacent touch-sensitive segments and configured to transmit a signal corresponding to a location of a touch-sensitive segment responsive to placement of an operator digit over or in contact with that respective segment.

19. The apparatus of claim 18, further including a microcontroller operably coupled with each of the first, second and third sets of PCBs and configured to convert a signal from a touch-sensitive segment to a distance.

20. The apparatus of claim 19, further including a main controller operably coupled to each microcontroller of the first, second and third sets of PCBs to receive distance signals therefrom and convert the distance signals to length, width and height measurements of the object.

21. The apparatus of claim 18, wherein the at least a second set of PCBs is located proximate the other vertical wall or proximate an end of the table opposite the other vertical wall.

22. The apparatus of claim 18, wherein one or more of the at least one first, second and third sets of PCBs comprises multiple, mutually parallel, laterally spaced sets of PCBs.

23. The apparatus of claim 18, wherein at least one set of the at least one first, second and third sets of PCBs is slidably mounted respectively to the horizontal table, the vertical wall and the other vertical wall in a direction parallel to a dimension to be measured by the respective set of PCBs.

24. A method of measuring dimensions of an object, the method comprising:
placing an object to be measured at a junction of a table surface and surfaces of two mutually perpendicular vertical walls;
emitting a first laser beam horizontally over the table surface toward the object and perpendicular to one of the vertical walls, moving the first laser beam horizontally from a position where the object interferes with the laser beam until the object no longer interferes with the laser beam, and determining a horizontal distance of the first laser beam from the junction;
emitting a second laser beam vertically over the table surface toward the object and perpendicular to the table surface, moving the second laser beam horizontally from a position where the object interferes with the second laser beam until the object no longer interferes with the second laser beam, and determining a horizontal distance of the second laser beam from the junction; and
emitting a third laser beam horizontally over the table surface toward the object and perpendicular to the surface of the one of the vertical walls, moving the third laser beam vertically from a position where the object interferes with the third laser beam until the object no longer interferes with the third laser beam, and determining a vertical distance of the third laser beam from the junction.
